(19) United States
(12) Patent Application Publication
(10) Pub. No.: US 2017/0103895 A1
(43) Pub. Date: Apr. 13, 2017

(54) LASER IRRADIATION APPARATUS AND LASER IRRADIATION METHOD

(71) Applicants: KYUSHU UNIVERSITY, NATIONAL UNIVERSITY CORPORATION, Fukuoka (JP); GIGAPHOTON INC., Tochigi (JP)

(72) Inventors: Yousuke WATANABE, Fukuoka (JP); Hiroshi IKENOUE, Fukuoka (JP); Osamu WAKABAYASHI, Tochigi (JP)

(73) Assignees: KYUSHU UNIVERSITY, NATIONAL UNIVERSITY CORPORATION, Fukuoka (JP); GIGAPHOTON INC., Tochigi (JP)

(21) Appl. No.: 15/383,050

(22) Filed: Dec. 19, 2016

Related U.S. Application Data
(63) Continuation of application No. PCT/JP2014/072586, filed on Aug. 28, 2014.

(51) Int. Cl. H01L 21/223; H01L 21/324; H01L 21/67; H01L 21/268

(52) U.S. Cl. CPC H01L 21/2236; H01L 21/268; H01L 21/324; H01L 21/67115; B23K 2203/56

(57) ABSTRACT

A laser irradiation apparatus may include a plasma generator, a laser unit configured to output a pulsed laser light beam, and a controller. The plasma generator may be configured to supply an atmospheric pressure plasma containing a dopant to a predetermined region on a semiconductor material. The controller may be configured to control the plasma generator and the laser unit to perform one of first and second controls to thereby perform doping of the dopant into the semiconductor material. The first control may cause irradiation of the predetermined region with one or more pulses of the pulsed laser light beam from start to finish of supply of the atmospheric pressure plasma to the predetermined region. The second control may cause irradiation of the predetermined region with one or more pulses of the pulsed laser light beam after supply of the atmospheric pressure plasma to the predetermined region.

### CROSS REFERENCE TO RELATED APPLICATIONS

The present application is a continuation application of International Application No. PCT/JP2014/072586 filed on Aug. 28, 2014. The content of the application is incorporated herein by reference in its entirety.

### BACKGROUND

1. Technical Field

The present disclosure relates to a laser irradiation apparatus that irradiates a semiconductor material with laser light for doping and a laser irradiation method.

2. Related Art

Semiconductors are materials that constitute active elements of integrated circuits, power devices, light emitting diodes (LEDs), liquid crystal displays, and organic electroluminescence (EL) displays, and are absolutely necessary to manufacture electronic devices. In order to manufacture such active elements, it is necessary to implant a dopant into a semiconductor and activate the dopant, thereby modulating electrical properties of the semiconductor into n-type or p-type electrical properties.

Examples of existing methods of implanting a dopant into a semiconductor and activating the dopant may include an ion implantation method and a thermal diffusion method. In the thermal diffusion method, a substrate is heated at a high temperature in a gas containing a dopant to thermally diffuse the dopant from a surface of a semiconductor and activate the dopant.

The ion implantation method involves an ion implantation process and a thermal annealing process to modulate electrical properties of a semiconductor into n-type or p-type electrical properties. In the ion implantation process, a semiconductor substrate is irradiated with ions of dopant atoms that are accelerated at high speed to implant the dopant into the semiconductor. The thermal annealing process is performed to repair a defect inside the semiconductor caused by the ion implantation process and activate the dopant. The ion implantation method has some advantages including enabling local control of an ion implantation region with use of a mask such as a resist and precise control of a dopant concentration depth, and has superior control characteristics such as being used as integrated circuit manufacturing technology using silicon (Si). For example, reference is made Japanese Unexamined Patent Application Publication No. 2013-202689, Japanese Unexamined Patent Application Publication No. 2011-034767, Japanese Unexamined Patent Application Publication No. 2013-065433, Japanese Unexamined Patent Application Publication (Published Japanese Translation of PCT Application) No. JP2011-512038, Japanese Unexamined Patent Application Publication No. 2006-317981, Japanese Unexamined Patent Application Publication No. 2004-158564, and Japanese Unexamined Patent Application Publication No. 2001-223174.

### SUMMARY

A laser irradiation apparatus according to one aspect of the present disclosure may include a plasma generator, a laser unit, and a controller. The plasma generator may be configured to supply an atmospheric pressure plasma to a predetermined region on a semiconductor material. The atmospheric pressure plasma may contain a dopant. The laser unit may be configured to output a pulsed laser light beam. The controller may be configured to control the plasma generator and the laser unit to perform one of a first control and a second control to thereby perform doping of the dopant into the semiconductor material. The first control may cause irradiation of the predetermined region with one or more pulses of the pulsed laser light beam from start to finish of supply of the atmospheric pressure plasma to the predetermined region, and the second control may cause irradiation of the predetermined region with one or more pulses of the pulsed laser light beam after supply of the atmospheric pressure plasma to the predetermined region.

A laser irradiation method according to one aspect of the present disclosure may include: supplying an atmospheric pressure plasma to a predetermined region on a semiconductor material, the atmospheric pressure plasma containing a dopant; outputting a pulsed laser light beam; and performing one of a first control and a second control to thereby perform doping of the dopant into the semiconductor material. The first control may cause irradiation of the predetermined region with one or more pulses of the pulsed laser light beam from start to finish of supply of the atmospheric pressure plasma to the predetermined region, and the second control may cause irradiation of the predetermined region with one or more pulses of the pulsed laser light beam after supply of the atmospheric pressure plasma to the predetermined region.

### BRIEF DESCRIPTION OF THE DRAWINGS

Some example embodiments of the present disclosure are described below as mere examples with reference to the accompanying drawings.

FIG. 1 schematically illustrates a configuration example of a laser irradiation apparatus according to a first embodiment.

FIG. 2 illustrates an example of a flow of control of the laser irradiation apparatus according to the first embodiment.

FIG. 3 illustrates an example of a relationship between a laser medium and a wavelength and photon energy of a pulsed laser light beam.

FIG. 4 illustrates an example of a correspondence between band gaps of semiconductor materials and kinds of laser units that are applicable to doping.

FIG. 5 illustrates current-voltage characteristics of a pn junction diode configured of an n-type region doped with nitrogen and a p-type region of a 4H—SiC substrate.

FIG. 6 illustrates reverse recovery characteristics of the pn junction diode configured of the n-type region doped with nitrogen and the p-type region of the 4H—SiC substrate.

FIG. 7 schematically illustrates a configuration example of a laser irradiation apparatus according to a second embodiment.

FIG. 8 illustrates examples of dopant gas species and elements to be doped.

FIG. 9 schematically illustrates a configuration example of a laser irradiation apparatus according to a third embodiment.

FIG. 10 illustrates an example of a flow of control of the laser irradiation apparatus according to the third embodiment.

FIG. 11 schematically illustrates a configuration of a main part of a laser irradiation apparatus according to a fourth embodiment.

FIG. 12 schematically illustrates an example of a fly-eye lens for formation of a linear laser beam.

FIG. 13 schematically illustrates a configuration example of a plasma generating system including a plasma generator.

FIG. 14 illustrates an example of a hardware environment of a controller.

### DETAILED DESCRIPTION

### <Contents>

### [1. Overview]

### [2. Terms]

### [3. Issues]

3.1 Thermal Diffusion Method

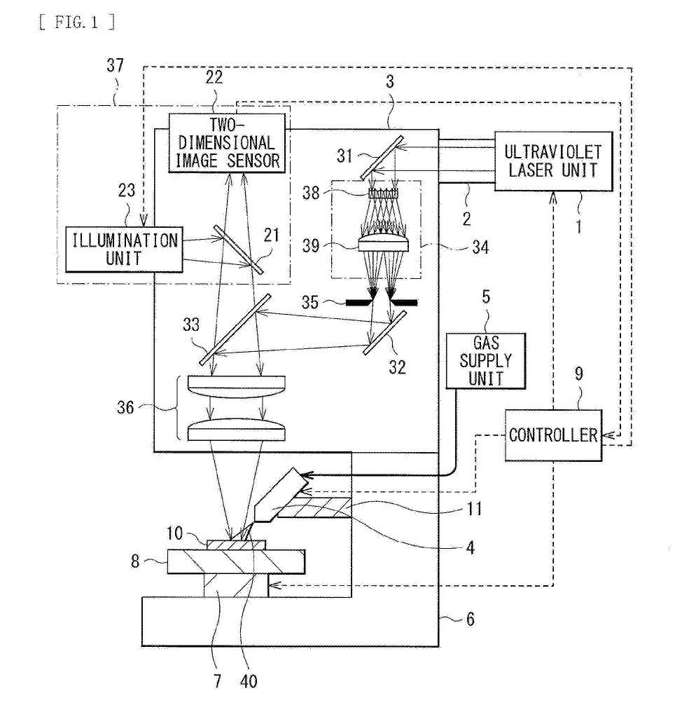

3.2 Ion Implantation Method

[4. First Embodiment] (Laser irradiation apparatus including plasma generator) (FIGS. 1 to 6)

4.1 Configuration (FIG. 1)

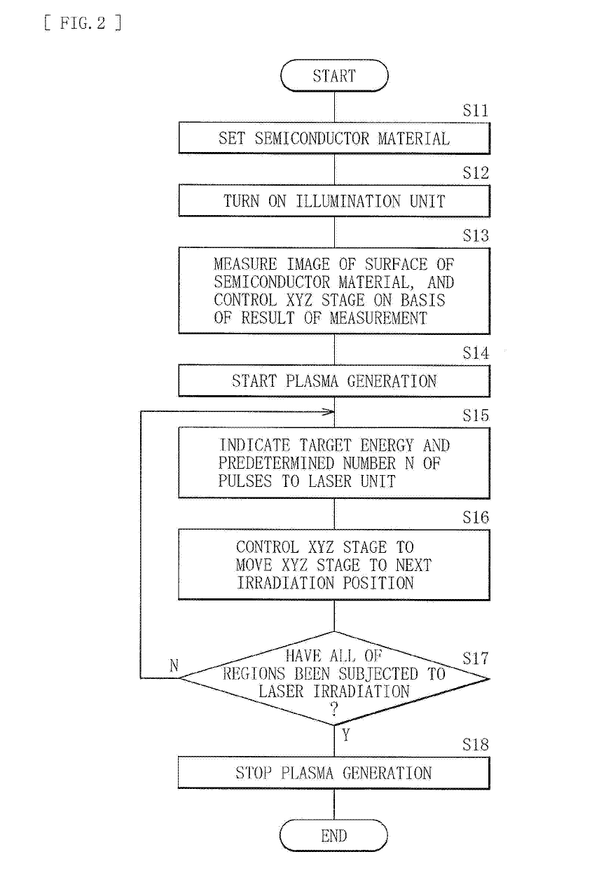

4.2 Operation (FIG. 2)

4.3 Effect

4.4 Modification Example

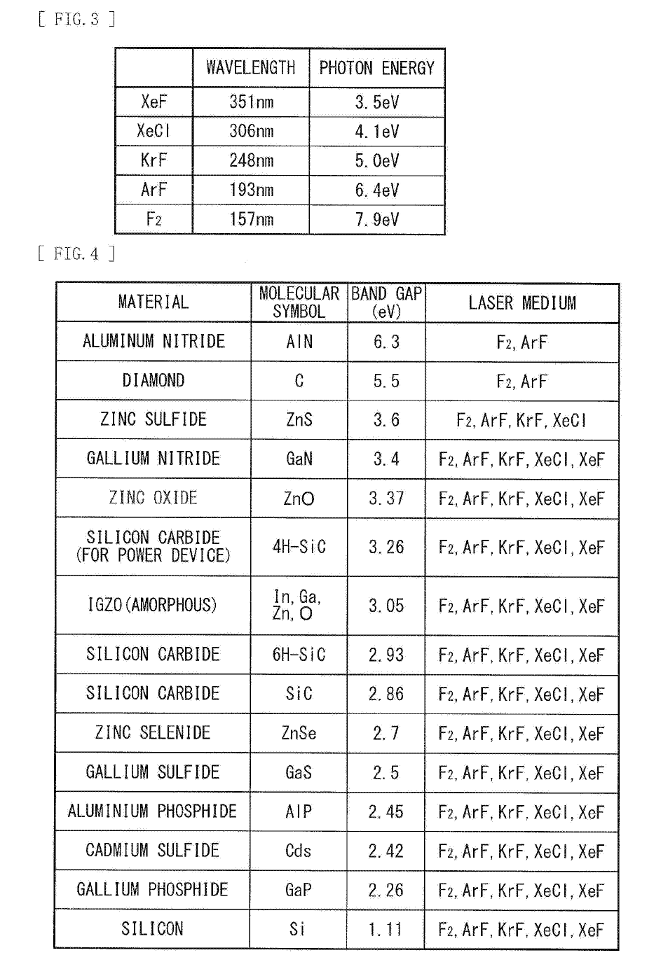

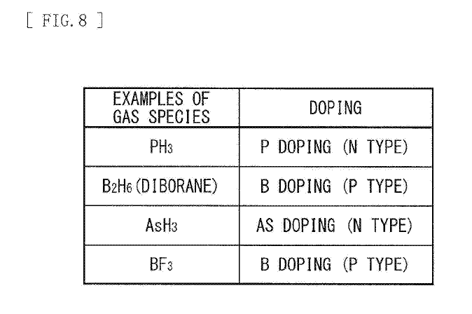

4.5 Specific Examples (FIGS. 3 to 6)
4.5.1 Relationship between Semiconductor Material and Photon Energy of Pulsed Laser Light Beam
4.5.2 Test on Laser Irradiation apparatus
4.5.3 Pulse Width of Pulsed Laser Light Beam
   [5. Second Embodiment] (Laser irradiation apparatus including chamber and plasma generator) (FIGS. 7 and 8)

5.1 Configuration

5.2 Operation

5.3 Effect

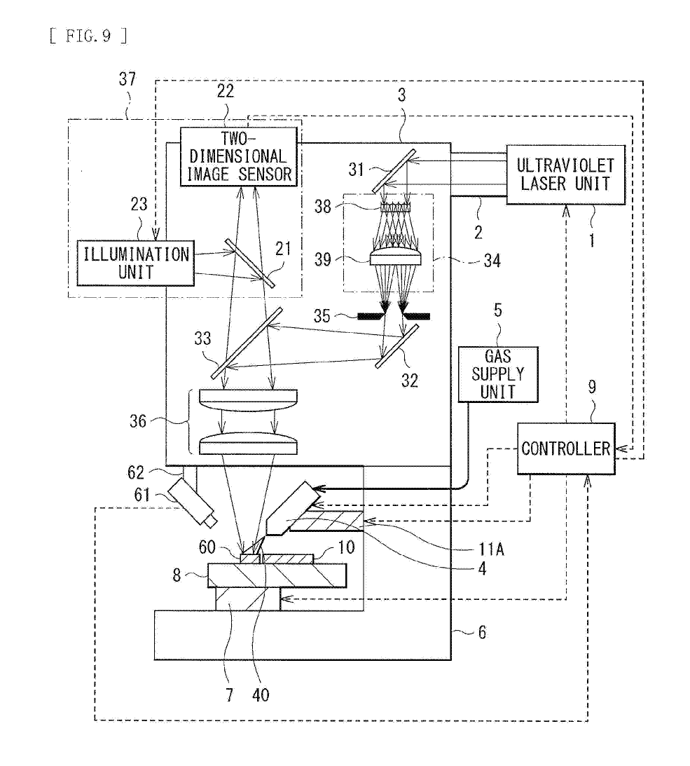

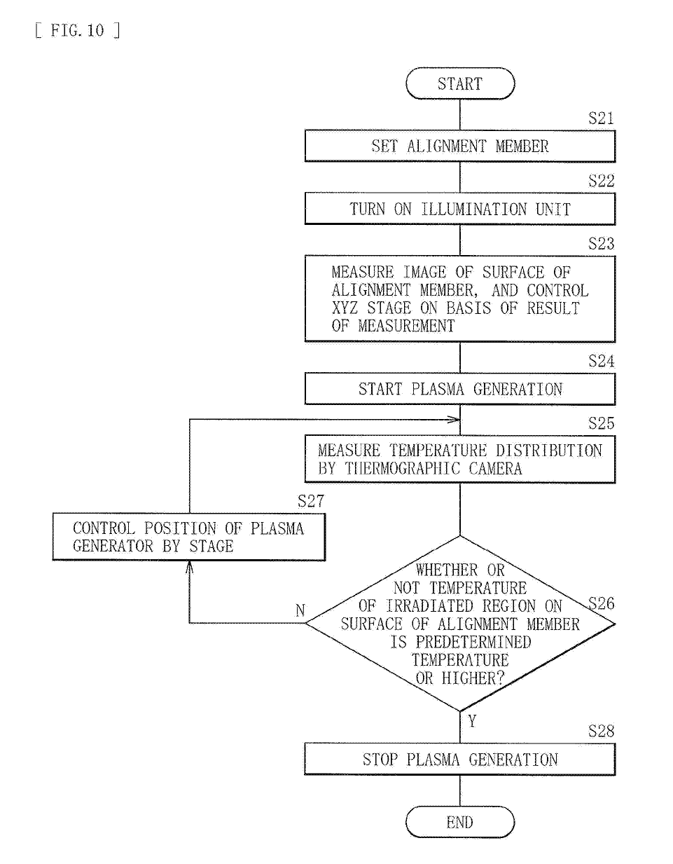

5.4 Modification Example

[6. Third Embodiment] (Laser irradiation apparatus that performs alignment of laser light beam irradiated region and plasma supply region) (FIGS. 9 and 10)

6.1 Configuration

6.2 Operation

6.3 Effect

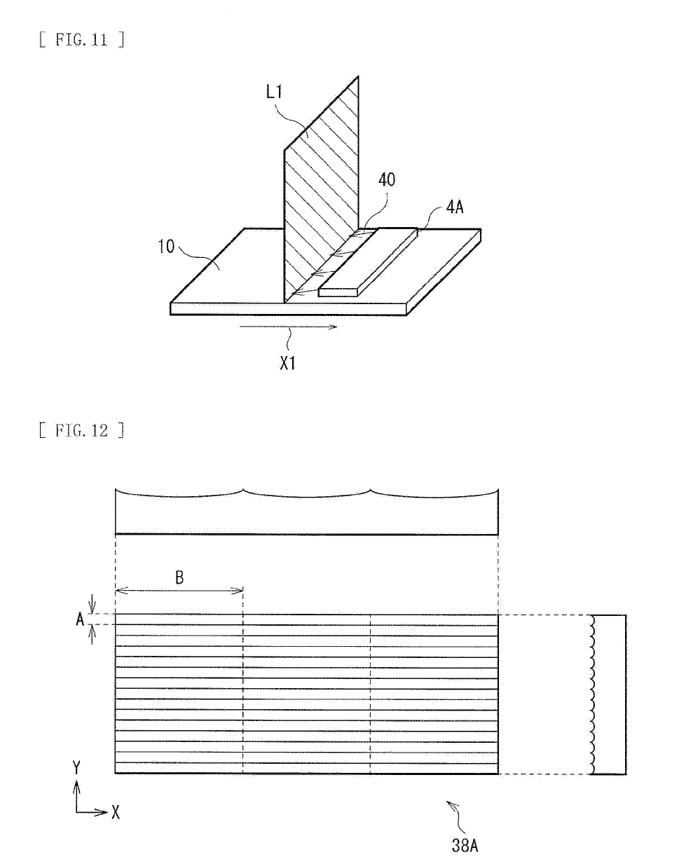

6.4 Modification Example

[7. Fourth Embodiment] (Laser irradiation apparatus that performs irradiation with linear laser beam) (FIGS. 11 and 12)

7.1 Configuration and Operation

7.2 Examples of Optical System for Formation of Linear Laser Beam

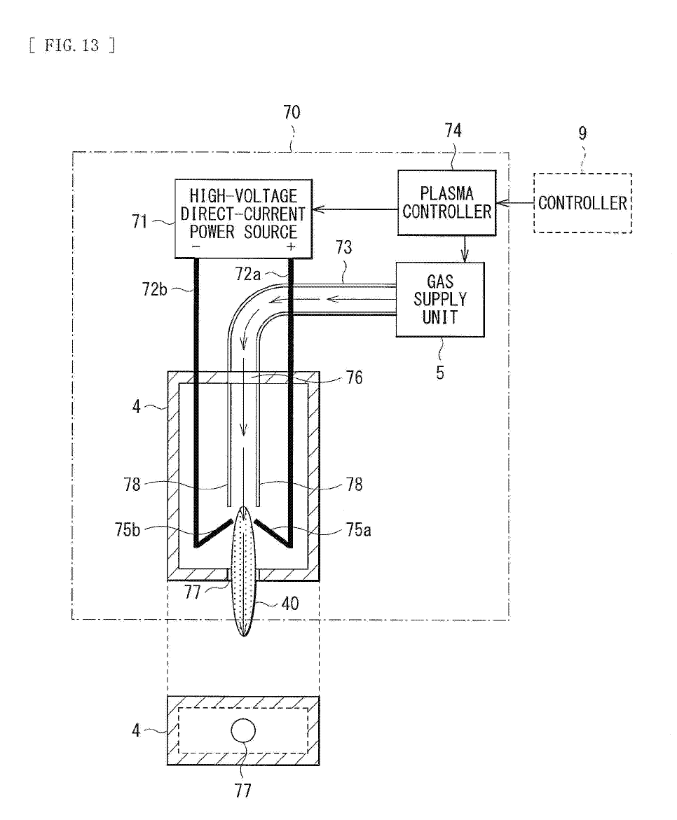

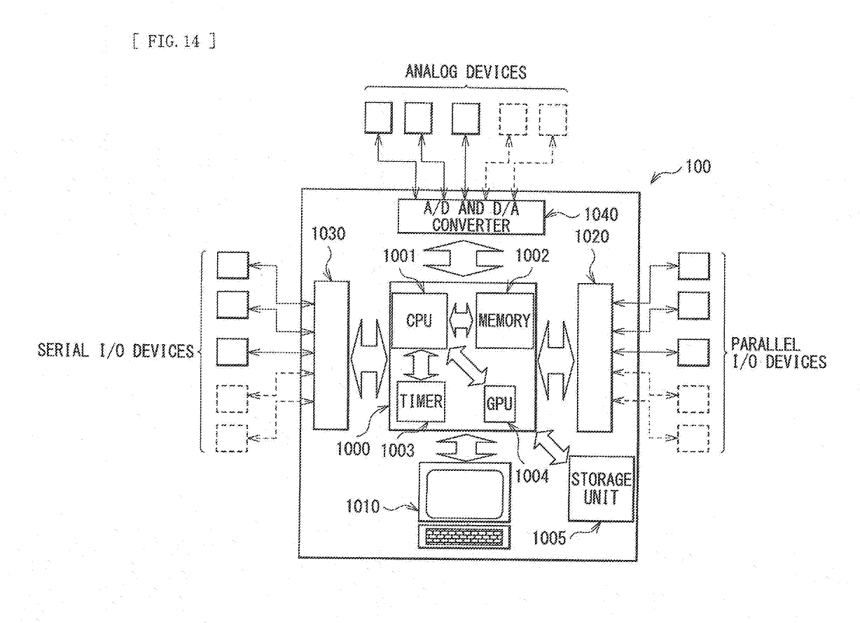

7.3 Modification Example

[8. Fifth Embodiment] (Specific example of plasma generator) (FIG. 13)

8.1 Configuration

8.2 Operation and Effect

8.3 Modification Example

### [9. Hardware Environment of Controller] (FIG. 14)

### [10. Et Cetera]

In the following, some example embodiments of the present disclosure are described in detail with reference to the drawings. Example embodiments described below each illustrate one example of the present disclosure and are not intended to limit the contents of the present disclosure. Further, all of the configurations and operations described in each example embodiment are not necessarily essential for the configurations and operations of the present disclosure. Note that like components are denoted by like reference numerals, and redundant description thereof is omitted.

### 1. Overview

The present disclosure relates to a laser irradiation apparatus configured to irradiate a semiconductor with a plasma and a pulsed ultraviolet laser light beam, for example. The plasma contains an element serving as a dopant.

In the present disclosure, there is provided a laser irradiation apparatus including a light source, an irradiation optical system, and a plasma supply unit. The light source is configured to output a laser light beam. The irradiation optical system is configured to guide the laser light beam to a semiconductor material. The plasma supply unit is configured to supply a plasma to at least a laser irradiated region. The plasma to be supplied may be preferably an atmospheric pressure plasma. The laser light beam may be preferably a pulsed laser light beam. The plasma to be supplied may contain at least an element serving as a dopant for the semiconductor material. Non-limiting examples of the plasma may include a nitrogen plasma. The element serving as a dopant may include one or more selected from the group consisting of nitrogen (N), phosphorus (P), boron (B), and arsenic (As). The laser light beam may be a laser light beam having a wavelength that is absorbed by a desired semiconductor material. A laser light beam generated by an excimer laser may be used. Non-limiting examples of the excimer laser may include a F₂ excimer laser, an ArF excimer laser, a KrF excimer laser, a XeCl excimer laser, and a XeF excimer laser.

When the dopant converted to a plasma state is exposed to a semiconductor material, the dopant may be adsorbed on dangling bonds on a surface of the semiconductor material to cover the surface of the semiconductor material. Irradiating such a dopant-covered surface with a laser light beam may cause dopant atoms on the surface to be diffused into the semiconductor and be activated, thereby enabling doping. Moreover, using the pulsed laser light beam may make it possible to alternately perform exposure to the plasma and laser irradiation, and control of the number of laser irradiation shots may make it possible to change a doping concentration. In order to sufficiently supply the plasma between irradiation pulses, it is necessary to increase a pressure of the plasma, and it may be difficult to perform high-concentration doping with use of an existing low-pressure plasma. In the present disclosure, using an atmospheric pressure plasma may make it possible to sufficiently supply the plasma to the surface of the semiconductor material.

### 2. Terms

### (Definition of Atmospheric Pressure Plasma)

A plasma generated at an atmospheric pressure is referred to as “atmospheric pressure plasma”. The atmospheric pressure plasma is a plasma that is generated without needing a large-scale vacuum pumping unit. The atmospheric pressure plasma in a state in which an electron temperature (Te) is high, whereas an ion temperature is substantially equal to a gas temperature (Tg) and close to a room temperature, that is, in a thermally non-equilibrium state (Te>>Ti≈Tg) is referred to as “non-equilibrium plasma” or “low-temperature plasma”.

### 3. Issues

### 3.1 Thermal Diffusion Method

In a thermal diffusion method, it is necessary to maintain an entire substrate at a high temperature; therefore, patterning using a resist is difficult, and it is difficult to locally control a region where a dopant is to be diffused. Moreover, in the thermal diffusion method, the temperature of the entire substrate is kept at a high temperature. Hence, in a case with a semiconductor material in which a defect is likely to be produced inside the substrate in a temperature range necessary for thermal diffusion, it is difficult to modulate electrical properties of the semiconductor material into n-type or p-type electrical properties by the thermal diffusion method. Non-limiting examples of the semiconductor material may include oxide semiconductors such as SiC, ZnO, and IGZO (Registered Trademark). Note that IGZO is an abbreviation of a semiconductor of indium, gallium, zinc, and oxygen.

### 3.2 Ion Implantation Method

In contrast, in an ion implantation method, it is difficult, in principle, to avoid production of a defect inside a semiconductor during ion implantation. Accordingly, in a material in which thermal repair of a defect is difficult, degradation in properties and restriction on a dopant concentration may occur. Non-limiting examples of the material may include semiconductor materials such as SiC, ZnO, and IGZO.

For example, in a case with SiC, in order to minimize defects produced during the ion implantation or in order to repair as many defects as possible, it is necessary to keep a substrate temperature at a high temperature during ion implantation, and an extremely high temperature of 1800° C. is necessary in thermal annealing after the ion implantation. However, high-concentration doping is difficult even though such an extremely high-temperature process is used. Further, in the high-temperature annealing at 1800° C., a defect may be produced even in a region inside the substrate that has not been subjected to ion implantation, thereby causing degradation in properties.

Moreover, in ZnO, IGZO, and other semiconductor materials, an oxygen depletion defect is easily produced by ion implantation, and the thus-produced depletion defect may cause electrons to be emitted, thereby producing n-type ZnO or an n-type semiconductor material. When ions of Sb, N, or P known as a p-type dopant for ZnO are implanted into ZnO, an oxygen depletion defect is produced at the same time, and not only holes that are p-type carriers but also electrons that are n-type carriers are produced concurrently; therefore, it is expected that it is difficult to produce the p-type ZnO. In a case with the semiconductor materials, such as SiC, ZnO, and IGZO, in which a defect is easily produced by ion implantation and it is difficult to repair the defect by thermal annealing for activation that is to be performed after the ion implantation, the ion implantation method has issues such as restriction on the dopant concentration and difficulty in modulation of the electrical properties into n-type or p-type electrical properties.

### [4. First Embodiment] (Laser Irradiation Apparatus Including Plasma Generator)

### 4.1 Configuration

FIG. 1 schematically illustrates a configuration example of a laser irradiation apparatus including a plasma generator 4 according to a first embodiment of the present disclosure.

The laser irradiation apparatus may include an ultraviolet laser unit 1, an optical path tube 2, an irradiation optical system 3, a plasma generator 4, a gas supply unit 5, a frame 6, an XYZ stage 7, a table 8, and a controller 9.

The optical path tube 2 may be disposed in an optical path of a laser light beam between an exit port for the laser light beam of the ultraviolet laser unit 1 and an entrance port for the laser light beam of the irradiation optical system 3.

The ultraviolet laser unit 1 may output a pulsed laser light beam of ultraviolet light having higher photon energy than a band gap of the semiconductor material 10. The ultraviolet laser unit 1 may be a discharge-excited gas laser unit using a laser medium containing one or more selected from the group consisting of F₂, ArF, KrF, XeCl, and XeF, for example. For example, a pulse width of the pulsed laser light beam of the ultraviolet light at full width half maximum may preferably lie in a range from 1 nanosecond (ns) to 1000 ns both inclusive, and more preferably in a range from 10 ns to 100 ns both inclusive.

The irradiation optical system 3, the XYZ stage 7, and a holder 11 may be fixed to the frame 6.

The semiconductor material 10 may be 4H—SiC. The semiconductor material 10 may be fixed to the XYZ stage 7 with the table 8 in between.

The irradiation optical system 3 may include a first high reflection mirror 31, a second high reflection mirror 32, a third high reflection mirror 33, a beam homogenizer 34, a mask 35, a transfer optical system 36, and a monitor optical system 37.

The first high reflection mirror 31 may be disposed to allow a laser light beam from the ultraviolet laser unit 1 to enter the beam homogenizer 34.

The beam homogenizer 34 may include, for example, a fly-eye lens 38 and a capacitor optical system 39. The fly-eye lens 38 and the capacitor optical system 39 may be disposed to illuminate the mask 35 through Koehler illumination. In other words, a focal point of the fly-eye lens 38 may be substantially coincident with a position of a front focal surface of the capacitor optical system 39, and the mask 35 may be disposed at a position of a rear focal point of the capacitor optical system 39. The capacitor optical system 39 may be configured of a combination of a convex lens and a concave lens.

The second high reflection mirror 32 and the third high reflection mirror 33 may be disposed to allow the laser light beam to enter the transfer optical system 36. The third high reflection mirror 33 may be configured of a substrate coated with a film. The substrate may allow visible light to pass therethrough, and the film may allow visible light to pass therethrough at high transmittance and may reflect laser light at high reflectivity. The substrate may be made of CaF₂ crystal or synthetic quartz. The transfer optical system 36 may be disposed to allow an image of the mask 35 to be transferred to a surface of the semiconductor material 10 on the table 8.

The monitor optical system 37 may include a half mirror 21, a two-dimensional image sensor 22, and an illumination unit 23.

The illumination unit 23 may include a lamp configured to emit visible light. The half mirror 21 may be a mirror configured of a substrate coated with a film. The substrate may allow visible light to pass therethrough. The film may reflect about 50% of visible light and may allow about 50% of the visible light to pass therethrough. The illumination unit 23 and the half mirror 21 may be disposed to illuminate a laser light beam irradiated surface of the semiconductor material 10 with the visible light through the third high reflection mirror 33 and the transfer optical system 36. The two-dimensional image sensor 22 may be an imaging device such as a CCD (charge coupled device) in which photodiodes are two-dimensionally provided. The two-dimensional image sensor 22 may be disposed so that the imaging device is located at a position where an image of a predetermined region on the semiconductor material 10, i.e., an image of a laser light beam irradiated region on the semiconductor material 10 is formed through the transfer optical system 36, the third high reflection mirror 33, and the half mirror 21.

The plasma generator 4 may be fixed to the holder 11 to allow a plasma 40 to be supplied to the predetermined region on the semiconductor material 10, i.e., the laser light beam irradiated region on the semiconductor material 10. The plasma generator 4 may include an unillustrated high-voltage power source. The plasma generator 4 may be coupled to the gas supply unit 5 through piping. The gas supply unit 5 may be configured to supply a gas serving as a material of a dopant. The gas serving as the material of the dopant may be an atmospheric nitrogen gas, for example.

### 4.2 Operation

In the laser irradiation apparatus illustrated in FIG. 1, the controller 9 may turn on the lamp of the illumination unit 23 of the monitor optical system 37 and may control the XYZ stage 7 to form the image of the laser light beam irradiated region on the semiconductor material 10 on the two-dimensional image sensor 22. Thereafter, the controller 9 may control the unillustrated high-voltage power source of the plasma generator 4 to supply the plasma 40 to the laser light beam irradiated region on the semiconductor material 10. As a result, for example, a nitrogen plasma may be supplied as the plasma 40 from the plasma generator 4 to the surface of the semiconductor material 10. When the semiconductor material 10 is exposed to nitrogen or any other element converted to a plasma state, nitrogen or the other element may be adsorbed on dangling bonds on the surface of the semiconductor material 10 to cover the surface of the semiconductor material 10 with an element serving as a dopant such as nitrogen.

The controller 9 may transmit a control signal indicating target energy (mJ) and a predetermined number N of pulses to the ultraviolet laser unit 1 to allow a fluence F (mJ/cm²) of the laser light beam irradiated region on the semiconductor material 10 to become a predetermined value. As a result, a pulsed laser light beam of ultraviolet light may be outputted from the ultraviolet laser unit 1, and the pulsed laser light beam may pass through the optical path tube 2 to enter the entrance port of the irradiation optical system 3. The pulsed laser light beam may enter the beam homogenizer 34 through the first high reflection mirror 31. The pulsed laser light beam may be homogenized by the beam homogenizer 34, and may illuminate the mask 35 through Koehler illumination. The pulsed laser light beam having passed through the mask 35 may enter the transfer optical system 36 through the second high reflection mirror 32 and the third high reflection mirror 33. The pulsed laser light beam having passed through the transfer optical system 36 may pass through the exit port of the irradiation optical system 3 to be applied to a mask image region on the surface of the semiconductor material 10.

At this occasion, the surface of the semiconductor material 10 that is covered with the element serving as a dopant such as nitrogen may be irradiated with N pulses of a pulsed laser light beam having the fluence F that enables doping. As a result, irradiation with the pulsed laser light beam of ultraviolet light may make it possible to diffuse nitrogen atoms or other element atoms on the surface of the semiconductor material 10 into the semiconductor and activate the nitrogen atoms or the other element atoms, thereby enabling doping. Moreover, using the pulsed laser light beam may make it possible to alternately perform exposure to the plasma 40 and laser irradiation, and controlling the number of shots of laser irradiation may make it possible to change a concentration of the element serving as a dopant such as nitrogen.

As described above, the controller 9 may control the plasma generator 4 and the ultraviolet laser unit 1 to perform doping of the dopant into the semiconductor material 10. In this case, the controller 9 may perform one of the following first control and the following second control. More specifically, the controller 9 may control the plasma generator 4 and the ultraviolet laser unit 1 to perform the first control that causes irradiation with one or more pulses of the pulsed laser light beam from start to finish of supply of the plasma 40 to the predetermined region on the semiconductor material 10. Moreover, the controller 9 may control the plasma generator 4 and the ultraviolet laser unit 1 to perform the second control that causes irradiation with one or more pulses of the pulsed laser light beam after supply of the plasma 40 to the predetermined region on the semiconductor material 10.

In the following, description is given of an operation flow of the laser irradiation apparatus with reference to FIG. 2.

First, the semiconductor material 10 may be set on the table 8 (step S11). Thereafter, the controller 9 may turn on the lamp of the illumination unit 23 (step S12) to illuminate the surface of the semiconductor material 10. Subsequently, the controller 9 may measure an image of the surface of the semiconductor material 10 by the two-dimensional image sensor 22, and may control the XYZ stage 7 on the basis of a result of the measurement (step S13). At this occasion, the controller 9 may control a Z axis of the XYZ stage 7 to make the image of the surface of the semiconductor material 10 clear. Moreover, the controller 9 may control XY axes of the XYZ stage 7 to locate the semiconductor material 10 at a desired first irradiation position.

Next, the controller 9 may transmit a plasma generation signal to the plasma generator 4 to start plasma generation (step S14), and may supply the plasma 40 to the predetermined region on the semiconductor material 10. Thereafter, the controller 9 may transmit a control signal indicating the target energy and the predetermined number N of pulses to have the fluence F that enables doping (step S15). As a result, the predetermined number N of pulses of the pulsed laser light beam may be applied to the predetermined region at the fluence F that enables doping to perform doping.

Subsequently, the controller 9 may control the XYZ stage 7 to move the semiconductor material 10 to the next irradiation position (step S16). The controller 9 may determine whether all of regions that are necessary to be doped have been subjected to laser irradiation (step S17). In a case in which all of the regions have not yet been subjected to laser irradiation (step S17; N), the control by the controller 9 may return to the process in the step S15. In a case in which all of the regions have been subjected to laser irradiation (step S17; Y), the controller 9 may control the plasma generator 4 to stop the plasma generation (step S18), and may end the control.

### 4.3 Effect

According to the first embodiment, even the semiconductor material 10 having a high band gap such as 4H—SiC and ZnO may be doped by irradiation with the pulsed laser light beam of ultraviolet light having higher photon energy than the band gap of the semiconductor material 10. Moreover, supplying, for example, a nitrogen plasma as the plasma 40 may make it possible to perform doping into the semiconductor material 10 by a simple laser irradiation apparatus.

### 4.4 Modification Example

The above description involves an example in which the monitor optical system 37 and the beam homogenizer 34 are provided in the irradiation optical system 3; however, the first embodiment is not limited to this example, and one or both of the monitor optical system 37 and the beam homogenizer 34 may not necessarily be provided.

### 4.5 Specific Examples

### 4.5.1 Relationship Between Semiconductor Material and Photon Energy of Pulsed Laser Light Beam

FIG. 3 illustrates an example of a relationship between a laser medium of the ultraviolet laser unit 1 and a wavelength and photon energy of a pulsed laser light beam. As illustrated in FIG. 3, the photon energy of the pulsed laser light beam when the laser medium of the ultraviolet laser unit 1 is F₂, ArF, KrF, XeCl, and XeF may respectively be 7.9 eV, 6.4 eV, 5.0 eV, 4.1 eV, and 3.5 eV. Moreover, the wavelength of the pulsed laser light beam when the laser medium is F₂, ArF, KrF, XeCl, and XeF may respectively be 157 nm, 193 nm, 248 nm, 306 nm, and 351 nm

Herein, in order to enable doping, the photon energy of the pulsed laser light beam to be outputted from the ultraviolet laser unit 1 may be necessary to be higher than the band gap of the semiconductor material 10. In other words, the photon energy>the band gap may be necessary.

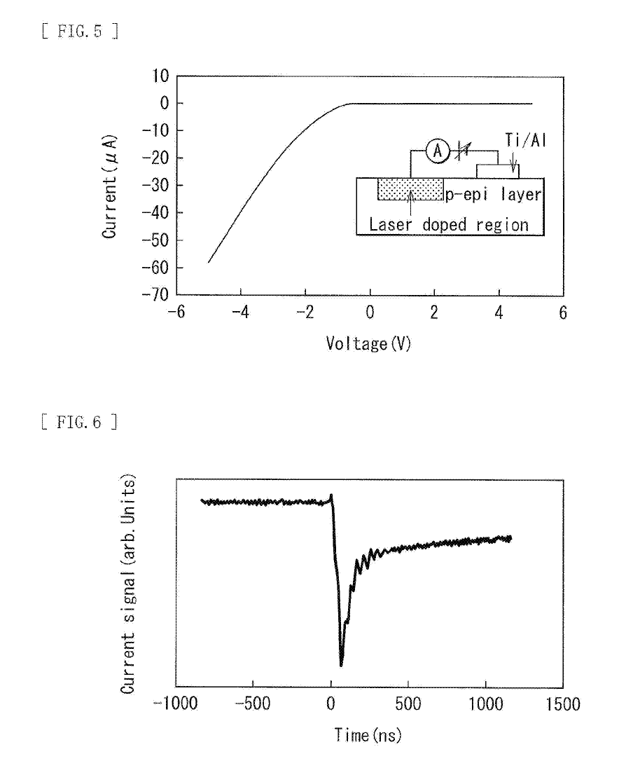

FIG. 4 illustrates an example of a correspondence between the band gap of the semiconductor material 10 and the kind of the ultraviolet laser unit 1 that is applicable to doping. As illustrated in FIG. 4, for example, in a case with a wide gap semiconductor such as 4H—SiC used for a power device, in order to enable doping, a pulsed laser light beam having photon energy higher than 3.26 eV may be necessary. In other words, a pulsed laser light beam having a wavelength of 380 nm or less may be necessary. Accordingly, the wavelength of the pulsed laser light beam to be outputted from the ultraviolet laser unit 1 may preferably lie in a range from 157 nm to 380 nm both inclusive. In this case, the ultraviolet laser unit 1 may be a solid-state laser unit as long as the solid-state laser unit is configured to output a pulsed laser light beam having a wavelength of 380 nm or less. For example, the ultraviolet laser unit 1 may be a solid-state laser unit configured to generate a third harmonic (having a wavelength of 355 nm), a fourth harmonic (having a wavelength of 266 nm), and a fifth harmonic (having a wavelength of 213 nm) of a YAG laser.

### 4.5.2 Test on Laser Irradiation Apparatus

A test on the laser irradiation apparatus was performed as follows.

### (Test Conditions)

The ultraviolet laser unit 1 was a KrF laser. The wavelength of the pulsed laser light beam was 248 nm, and the pulse width of the pulsed laser light beam at full width half maximum was about 55 ns. The semiconductor material 10 was a p-epi/n⁺ 4H—SiC (1000) substrate. The plasma 40 was an atmospheric nitrogen plasma. The pulsed laser light beam irradiated region on the semiconductor material 10 had a 340-μm by 150-μm rectangular shape. Irradiation with the pulsed laser light beam was performed under conditions that the fluence of the pulsed laser light beam was in a range from 2.0 J/cm² to 4.6 J/cm² both inclusive, and the number of shots of irradiation was in a range of 1 shot to 10 shots both inclusive.

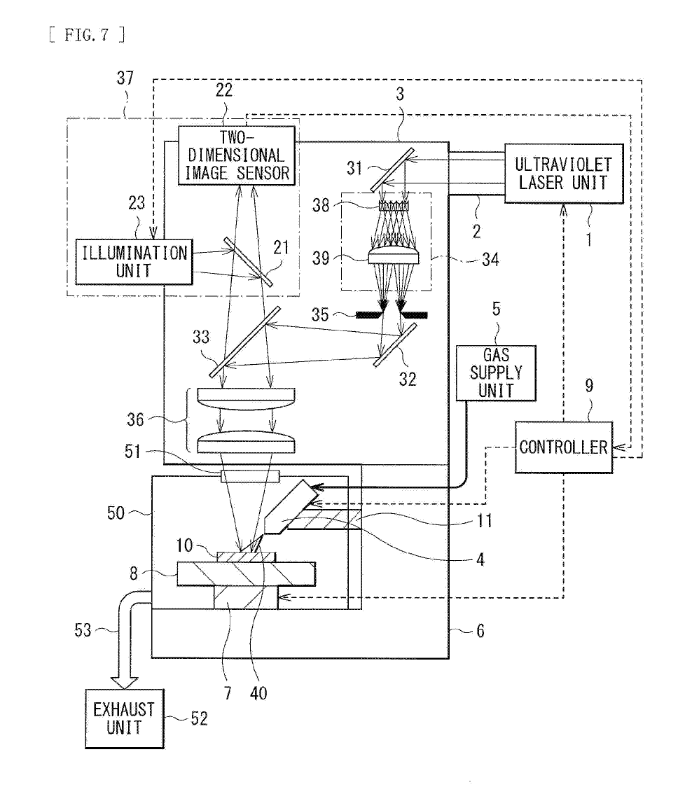

In the 4H—SiC substrate serving as the semiconductor material 10, a contact electrode of nitrogen atoms to a p-type region was formed by forming a Ti/Al film by a physical vapor deposition method, and annealing the Ti/Al film at 850° C. for 5 minutes in a vacuum. The p-type region subjected to the electrode deposition and a laser irradiated region constituted a pn junction diode, and current-voltage (I-V) characteristics and reverse recovery characteristics of the pn junction diode were measured. FIGS. 5 and 6 illustrate results of the measurement.

### (Test Results)

FIG. 5 illustrates the current-voltage characteristics of the pn junction diode configured of the n-type region doped with nitrogen by laser irradiation and the p-type region of the 4H—SiC substrate. In FIG. 5, a horizontal axis indicates voltage (V), and a vertical axis indicates current (μA). Clear rectification was confirmed by FIG. 5.

FIG. 6 illustrates the reverse recovery characteristics of the pn junction diode configured of the n-type region doped with nitrogen and the p-type region of the 4H—SiC substrate. In FIG. 6, a horizontal axis indicates time (ns), and a vertical axis indicates current (relative value). Reverse recovery time indicates recovery time of a thickness of a depletion region generated when a voltage to be applied to the diode is switched from reverse bias to forward vias. The reverse recovery time determined from FIG. 6 was about 260 ns, and a conclusion derived from the reverse recovery time is that rectification of the diode was definitely caused by pn junction. In other words, the nitrogen-doped region definitely exhibited n-type electrical properties, which indicated that implantation and activation of nitrogen concurrently occurred.

As described above, it was found out from the measured current-voltage characteristics and reverse recovery characteristics that laser irradiation of the 4H—SiC substrate in an atmospheric nitrogen plasma made it possible to concurrently perform implantation and activation of nitrogen at a low temperature.

### 4.5.3 Pulse Width of Pulsed Laser Light Beam

Table 1 illustrates results of diffusion depths of nitrogen and phosphorus by laser irradiation obtained by SIMS (Secondary Ion Mass Spectrometry) analysis.

TABLE 1

Number
of Shots

| | 1 shot | 10 shots |
|---|---|---|
| Nitrogen Diffusion Depth | 30 nm | 100 nm |
| Phosphorus Diffusion Depth | 4 nm | 14 nm |

A diffusion depth L may be determined as a depth to be 1/e of a surface concentration, where “e” is a natural logarithm. The diffusion depth L of an impurity in a solid may be represented by 2√(Dt), where “D” is a diffusion coefficient and “t” is diffusion time. In a case in which the diffusion time upon irradiation with the pulsed laser light beam is substantially equal to the pulse width and is represented by “τ”, the diffusion time t may be determined by t=Nτ, where “N” is the number of shots of irradiation. In other words, the diffusion depth L may be represented by the following expression:

L=2√(DNτ) (1)

When the diffusion coefficients of nitrogen and phosphorus by laser irradiation are determined by Table 1 and the expression (1), a diffusion coefficient DN of nitrogen and a diffusion coefficient DP of phosphorus may respectively be determined by DN=4.5*10⁻⁵ cm²/Vs and DP=1.0*10⁻⁶ cm²/Vs.

Tables 2 and 3 illustrate results of the diffusion depths of nitrogen and phosphorus with respect to the pulse width of the pulsed laser light beam and the number of shots of irradiation. These results were determined with use of the diffusion coefficients determined by experiment results.

TABLE 2
Diffusion Depth of Nitrogen by Laser Irradiation (nm)

| | Pulse Width | | | | | |
|---|---|---|---|---|---|---|
| | | | τ = 10 | τ = 50 | τ = 100 | τ = 1000 |
| | τ = 0.1 ns | τ = 1 ns | ns | ns | ns | ns |
| 1 Shot | 1.3 | 4.2 | 13.4 | 30.0 | 42.4 | 134.2 |
| 10 Shots | 4.2 | 13.4 | 42.4 | 94.9 | 134.2 | 424.3 |

TABLE 3
Diffusion Depth of Phosphorus by Laser Irradiation (nm)

| | Pulse Width | | | | | |
|---|---|---|---|---|---|---|
| | | | τ = 10 | τ = 50 | τ = 100 | τ = 1000 |
| | τ = 0.1 ns | τ = 1 ns | ns | ns | ns | ns |
| 1 Shot | 0.2 | 0.6 | 2.0 | 4.5 | 6.3 | 20.0 |
| 10 Shots | 0.6 | 2.0 | 6.3 | 14.1 | 20.0 | 63.2 |

It was found out from Tables 2 and 3 that the diffusion depth of a dopant changes depending on the kind of the dopant, the pulse width τ, and the number of shots of irradiation N. An implantation depth is one of most important control parameters in implantation and activation of an impurity. When the diffusion depth is too shallow, some issues may occur in a manufacturing stage. The issues may include elimination of a doped region by etching in a cleaning process or alloy reaction with an electrode metal. In other words, in order to electrically couple the doped region to a metal electrode, it may be necessary to appropriately control the pulse width and the number of shots of irradiation to prevent elimination of an impurity diffused region at least in a manufacturing process.

When a metal electrode of Al/Ti or Ni is formed on a SiC substrate, it may be necessary for the diffusion depth of the impurity to be 2 nm or more. It may be estimated that pulse widths necessary for doping of nitrogen and phosphorus by one shot of irradiation are respectively about 1 ns or more and 10 ns or more.

In a case in which the pulse width is increased, thermal stress by laser irradiation may increase to easily cause a crack in the substrate. In particular, when the pulse width is of the order of microseconds (μs), an influence of the thermal stress may increase to cause a crack in a processing-resistant material such as SiC. It is necessary to appropriately control the pulse width for a material to be subjected to doping. For example, in a case with SiC, the pulse width may be 1000 ns or less, and more preferably 100 ns or less.

### [5. Second Embodiment] (Laser Irradiation Apparatus Including Chamber and Plasma Generator)

### 5.1 Configuration

FIG. 7 schematically illustrates a configuration example of a laser irradiation apparatus including a chamber 50 and the plasma generator 4 according to a second embodiment of the present disclosure. Note that substantially same components as the components of the laser irradiation apparatus according to the foregoing first embodiment are denoted by same reference numerals, and redundant description thereof is omitted.

The laser irradiation apparatus according to the present embodiment may have a configuration in which the chamber 50, a window 51, an exhaust unit 52, and an exhaust pipe 53 are added to the laser irradiation apparatus illustrated in FIG. 1.

FIG. 8 illustrates examples of dopant gas species and elements to be doped that are applicable to the laser irradiation apparatus according to the present embodiment. The gas supply unit 5 in the present embodiment may supply a gas containing the gas species illustrated in FIG. 8 to the plasma generator 4. The element serving as a dopant may include one or more selected from the group consisting of phosphorus (P), boron (B), and arsenic (As). The gas species illustrated in FIG. 8 are noxious gases. Hence, the plasma generator 4, the semiconductor material 10, the table 8, and the XYZ stage 7 may be covered by the chamber 50 provided with the window 51. The chamber 50 may be coupled to the exhaust unit 52 through the exhaust pipe 53. The exhaust unit 52 may include a scrubber and an exhaust pump that are configured to remove noxious gas species.

### 5.2 Operation

In the laser irradiation apparatus illustrated in FIG. 7, the noxious gas species contained in a gas supplied from the gas supply unit 5 may be converted to a plasma state by the plasma generator 4 to be supplied to the surface of the semiconductor material 10 in the chamber 50. As a result, the surface of the semiconductor material 10 may be covered with the element serving as a dopant contained in the noxious gas species. When the ultraviolet laser unit 1 irradiates the surface of the semiconductor material 10 with the pulsed laser light beam of ultraviolet light through the irradiation optical system 3 and the window 51 in this state, the dopant may be doped into the semiconductor material 10. The exhaust unit 52 may exhaust a noxious gas generated upon generation of the plasma 40 from inside of the chamber 50.

### 5.3 Effect

According to the second embodiment, the exhaust unit 52 exhausts the noxious gas generated upon generation of the plasma 40 from the inside of the chamber 50, which may make it possible to achieve a safe laser irradiation apparatus.

### 5.4 Modification Example

The present embodiment involves an example in which the chamber 50 is disposed to cover the semiconductor material 10, the table 8, and the XYZ stage 7; however, the present embodiment is not limited to this example, and the chamber 50 may be disposed on the table 8 to cover the semiconductor material 10, for example.

### [6. Third Embodiment] (Laser Irradiation Apparatus that Performs Alignment of Laser Light Beam Irradiated Region and Plasma Supply Region)

### 6.1 Configuration

FIG. 9 schematically illustrates a configuration example of a laser irradiation apparatus according to a third embodiment of the present disclosure. Note that substantially same components as the components of the laser irradiation apparatus illustrated in FIG. 1 according to the foregoing first or second embodiment are denoted by same reference numerals, and redundant description thereof is omitted.

The laser irradiation apparatus according to the present embodiment may have a configuration in which a thermographic camera 61 and a holder 62 are added to the laser irradiation apparatus illustrated in FIG. 1. The holder 62 may be configured to hold the thermographic camera 61. Moreover, the laser irradiation apparatus according to the present embodiment may include a stage 11A in place of the holder 11 that is configured to fix the plasma generator 4. The stage 11A may control a position of the plasma generator 4 in accordance with an instruction from the controller 9.

In the present embodiment, an alignment member 60 may be disposed on the table 8 before doping into the semiconductor material 10. The alignment member 60 may be configured to cause the laser light beam irradiated region to be substantially coincident with a supply region of the plasma 40. A material of a surface of the alignment member 60 may be a material having low thermal conductivity such as polyimide. The surface of the alignment member 60 may have any of various shapes serving as a landmark for alignment such as a hole.

### 6.2 Operation

In the laser irradiation apparatus illustrated in FIG. 9, alignment of the laser light beam irradiated region and the supply region of the plasma 40 may be performed before doping into the semiconductor material 10. At this occasion, the controller 9 may control the XYZ stage 7 to cause the alignment member 60 to be located at a position to be irradiated with the pulsed laser light beam. Subsequently, the controller 9 may control the plasma generator 4 to generate the plasma 40 such as a nitrogen plasma. Thereafter, the controller 9 may measure a temperature distribution of the surface of the alignment member 60 by the thermographic camera 61. The controller 9 may control the stage 11A to adjust the position of the plasma generator 4 so that the temperature of the surface of the alignment member 60 reaches a predetermined temperature or higher.

Next, with reference to FIG. 10, description is given of an operation flow when the laser light beam irradiated region and the plasma supply region are aligned to be substantially coincident with each other.

First, the alignment member 60 may be set on the table 8 (step S21). Subsequently, the controller 9 may turn on the lamp of the illumination unit 23 (step S22) to illuminate the surface of the alignment member 60. Thereafter, the controller 9 may measure an image of the surface of the alignment member 60 by the two-dimensional image sensor 22, and may control the XYZ stage 7 on the basis of a result of the measurement (step S23). At this occasion, the controller 9 may control the Z axis of the XYZ stage 7 to make the image of the surface of the alignment member 60 clear. Moreover, the controller 9 may control the XY axes of the XYZ stage 7 to locate the alignment member 60 at a desired first irradiation position.

Next, the controller 9 may transmit a plasma generation signal to the plasma generator 4 to start plasma generation (step S24), and may supply the plasma 40 to the surface of the alignment member 60. Subsequently, the controller 9 may measure the temperature distribution of the surface of the alignment member 60 by the thermographic camera 61 (step S25). Thereafter, the controller 9 may determine whether or not the temperature of an irradiated region on the surface of the alignment member 60 is the predetermined temperature or higher (step S26). At this occasion, in a case in which the temperature of the irradiated region on the surface of the alignment member 60 is not the predetermined temperature or higher (step S26; N), the controller 9 may control the position of the plasma generator 4 by the stage 11A for the plasma 40 to cause the temperature of the irradiated region on the surface of the alignment member to be the predetermined temperature or higher (step S27), and the control by the controller 9 may return to the process in the step S25 again. In a case in which the temperature of the irradiated region on the surface of the alignment member 60 is the predetermined temperature or higher (step S26; Y), the controller 9 may control the plasma generator 4 to stop plasma generation (step S28). After the controller 9 performs the alignment operation described above, the controller 9 may perform doping into the semiconductor material 10 by a substantially similar procedure to the procedure in FIG. 2.

### 6.3 Effect

According to the third embodiment, the plasma 40 may be supplied to the surface of the alignment member 60, and the temperature distribution of the surface may measured by the thermographic camera 61. The plasma generator 4 is moved on the basis of the result, which may cause the laser light beam irradiated region and the plasma supply region to be substantially coincident with each other at high accuracy.

### 6.4 Modification Example

The present embodiment involves an example in which the stage 11A that moves the plasma generator 4 is controlled to adjust the position where the plasma 40 is to be supplied; however, the present embodiment is not limited to this example, and, for example, a unit configured to change a direction of a nozzle of the plasma generator 4 may be provided to control the direction of the nozzle.

### [7. Fourth Embodiment] (Laser Irradiation Apparatus that Performs Irradiation with Linear Laser Beam)

### 7.1 Configuration and Operation

FIG. 11 schematically illustrates an example of a configuration of a main part of a laser irradiation apparatus according to a fourth embodiment of the present disclosure. Note that substantially same components as the components of the laser irradiation apparatuses according to the foregoing first to third embodiments are denoted by same reference numerals, and redundant description thereof is omitted.

The semiconductor material 10 may be irradiated with a linear laser beam L1 as the pulsed laser light beam, as illustrated in FIG. 11. Moreover, a plasma generator 4A having a plurality of nozzles may supply the plasma 40 to a position to be irradiated with the linear laser beam L1. The plasma generator 4A having the plurality of nozzles may be one of atmospheric pressure plasma generators disclosed in Japanese Unexamined Patent Application Publication No. 2011-034767 and Japanese Unexamined Patent Application Publication No. 2013-065433.

In the laser irradiation apparatus according to the present embodiment, irradiation with the linear laser beam L1 and supply of the plasma 40 may be performed while moving the semiconductor material 10 to a direction indicated by an arrow X1 to perform doping into a desired region in the semiconductor material 10.

Moreover, the laser irradiation apparatus illustrated in FIG. 1 or FIG. 7 may be changed as follows. The beam homogenizer 34 may be changed to the beam homogenizer 34 configured to homogenize the linear laser beam L1. Moreover, the shape of the mask 35 may be changed to a slit shape. An image of the mask 35 may be transferred to the surface of the semiconductor material 10 to irradiate the surface of the semiconductor material 10 with the homogenized linear laser beam L1.

### 7.2 Examples of Optical System for Formation of Linear Laser Beam

FIG. 12 illustrates an example of a fly-eye lens 38A configured to generate the rectangular or linear laser beam L1 through Koehler illumination. In FIG. 12, a plan view, a front view, and a side view are respectively illustrated in a central part, above the plan view, and at the right of the plan view.

### (Configuration)

The fly-eye lens 38A may include a plurality of first cylindrical concave lenses. The first cylindrical concave lenses may be formed on a front surface of a substrate by arranging cylindrical surfaces having a concave surface shape in one line in a Y direction, and processing the cylindrical surfaces. The substrate may be made of a material allowing a pulsed laser light beam to pass therethrough. Non-limiting examples of the material may include synthetic quartz and CaF₂ crystal. Moreover, a plurality of second cylindrical concave lenses may be formed on a rear surface of the substrate by arranging cylindrical surfaces having a concave surface shape in one line in an X direction, and processing the cylindrical surfaces. A radius of curvature of each of the cylindrical surfaces on the front surface and the rear surface may be a value causing a focal point of the first cylindrical concave lens to be substantially coincident with a focal point of the second cylindrical concave lens. Herein, A<B may be preferable, where A is a pitch of the cylindrical surface in the Y direction, and B is a pitch of the cylindrical surface in the X direction.

### (Operation)

When the pulsed laser light beam passes through the fly-eye lens 38A illustrated in FIG. 12, a secondary light source may be produced at the focal point of the first and second cylindrical concave lenses. The capacitor optical system 39 may illuminate a position of a focal surface of the capacitor optical system 39 illustrated in FIG. 1 in a rectangular or linear shape through Koehler illumination. Herein, the shape of a region illuminated through Koehler illumination may be a similar shape to one lens (A by B) of the fly-eye lens 38A. As the mask 35, the rectangular or linear mask 35 that is slightly smaller than a uniformly illuminated shape may be provided. The image of the rectangular or linear mask 35 may be transferred onto the semiconductor material 10 by the transfer optical system 36 in FIG. 1. Thus, the rectangular or linear laser beam L1 may be applied onto the semiconductor material 10.

### 7.3 Modification Example

FIG. 11 illustrates an example of the plasma generator 4A having the plurality of nozzles; however, the present embodiment is not limited to this example, and a plasma generator having a rectangular opening serving as an exit port of the plasma 40 may be used, for example. Moreover, for example, a pattern may be formed on the mask 35 in the irradiation optical system 3, and the mask 35 may be moved to a direction opposite to the movement direction of the semiconductor material 10, and laser irradiation may be performed.

The embodiment in FIG. 12 involves an example in which the cylindrical surface having a concave surface shape is formed in the substrate allowing a laser light beam to pass therethrough; however, the embodiment is not limited to this example, and a cylindrical surface having a convex surface shape may be formed. Moreover, the substrate may be processed to form a Fresnel lens having the same function as the cylindrical lens.

### [8. Fifth Embodiment] (Specific Example of Plasma Generator)

### 8.1 Configuration

FIG. 13 schematically illustrates a configuration example of a plasma generating system including the plasma generator 4 according to a fifth embodiment of the present disclosure. Note that substantially same components as the components of the laser irradiation apparatuses according to the foregoing first to fourth embodiments are denoted by same reference numerals, and redundant description thereof is omitted.

Any of the laser irradiation apparatuses in the foregoing first to fourth embodiments may include a plasma generation system 70 illustrated in FIG. 13. The plasma generating system 70 may include the plasma generator 4, the gas supply unit 5, a high-voltage direct-current power source 71, wiring lines 72a and 72b, a gas piping 73, and a plasma controller 74.

The high-voltage direct-current power source 71 may be a power source configured to output a voltage of about 10 kV. A positive output terminal of the high-voltage direct-current power source 71 may be coupled to an electrode 75a in the plasma generator 4 through the wiring line 72a. A negative output terminal of the high-voltage direct-current power source 71 may be coupled to an electrode 75b in the plasma generator 4 through the wiring line 72b.

The gas supply unit 5 may be coupled to a gas feed port 76 through the gas piping 73. The gas supply unit 5 may cause a gas to flow at 4 to 15 liters per minute.

The plasma generator 4 may have the gas feed port 76, a gas exhaust port 77, and the electrodes 75a and 75b. A tip of the electrode 75a and a tip of the electrode 75b may be disposed to face each other with a predetermined gap in between. The gap herein may be about 10 mm A gas guide 78 may be disposed in a housing of the plasma generator 4 to cause the gas to flow through a space in the gap.

### 8.2 Operation and Effect

When the plasma generating system 70 receives the plasma generation signal from the controller 9, the plasma controller 74 may transmit a signal to the gas supply unit 5. The signal may instruct the gas supply unit 5 to cause a gas to flow at a predetermined flow rate in a range of 4 liters to 15 liters per minute, for example. As a result, the gas may be fed into the plasma generator 4 through the gas piping 73. Moreover, the gas guide 78 may cause the gas to pass through a space between the tip of the electrode 75a and the tip of the electrode 75b and be exhausted from the gas exhaust port 77.

The plasma controller 74 may transmit a signal to the high-voltage direct-current power source 71. The signal may instruct the high-voltage direct-current power source 71 to output a voltage of about 10 kV. As a result, an arc discharge may be generated between the tip of the electrode 75a and the tip of the electrode 75b. The arc discharge may be generated by insulation breakdown between the tip of the electrode 75a and the tip of the electrode 75b, and may fall in an equilibrium state mainly at a high gas molecule temperature. However, when a gas such as a nitrogen gas flows at high speed through the space between the tip of the electrode 75a and the tip of the electrode 75b in this state, a low gas molecule temperature region may be formed around the arc discharge to generate a glow discharge. An atmospheric pressure plasma having a low gas molecule temperature that is ionized by the glow discharge may flow downward by a high-speed gas flow to be quickly exhausted from the gas exhaust port 77. In other words, the gas exhaust port 77 may serve as an atmospheric pressure plasma generation section in which generation of a high-temperature plasma by an abnormal discharge is suppressed.

### 8.3 Modification Example

Generation of a plurality of linear plasmas 40 as illustrated in FIG. 11 may be achieved by arranging a plurality of plasma generators 4 as illustrated in FIG. 13 in one line. Moreover, in an example in FIG. 13, the plasma 40 is generated by application of a high direct-current voltage between the electrodes 75a and 75b; however, the present embodiment is not limited to this example. For example, application of a high voltage with a high frequency to an insulator may cause generation of a corona discharge, and a gas may flow to a surface of the corona discharge to generate the plasma 40. Thereafter, the plasma 40 may be supplied to a laser light beam irradiated section.

### 9. Hardware Environment of Controller

A person skilled in the art will appreciate that a general-purpose computer or a programmable controller may be combined with a program module or a software application to execute any subject matter disclosed herein. The program module, in general, may include one or more of a routine, a program, a component, a data structure, and so forth that each causes any process described in any example embodiment of the present disclosure to be executed.

FIG. 14 is a block diagram illustrating an exemplary hardware environment in which various aspects of any subject matter disclosed therein may be executed. An exemplary hardware environment 100 in FIG. 14 may include a processing unit 1000, a storage unit 1005, a user interface 1010, a parallel input/output (I/O) controller 1020, a serial I/O controller 1030, and an analog-to-digital (A/D) and digital-to-analog (D/A) converter 1040. Note that the configuration of the hardware environment 100 is not limited thereto.

The processing unit 1000 may include a central processing unit (CPU) 1001, a memory 1002, a timer 1003, and a graphics processing unit (GPU) 1004. The memory 1002 may include a random access memory (RAM) and a read only memory (ROM). The CPU 1001 may be any commercially-available processor. A dual microprocessor or any other multi-processor architecture may be used as the CPU 1001.

The components illustrated in FIG. 14 may be coupled to one another to execute any process described in any example embodiment of the present disclosure.

Upon operation, the processing unit 1000 may load programs stored in the storage unit 1005 to execute the loaded programs. The processing unit 1000 may read data from the storage unit 1005 together with the programs, and may write data in the storage unit 1005. The CPU 1001 may execute the programs loaded from the storage unit 1005. The memory 1002 may be a work area in which programs to be executed by the CPU 1001 and data to be used for operation of the CPU 1001 are held temporarily. The timer 1003 may measure time intervals to output a result of the measurement to the CPU 1001 in accordance with the execution of the programs. The GPU 1004 may process image data in accordance with the programs loaded from the storage unit 1005, and may output the processed image data to the CPU 1001.

The parallel I/O controller 1020 may be coupled to parallel I/O devices operable to perform communication with the processing unit 1000, and may control the communication performed between the processing unit 1000 and the parallel I/O devices. Non-limiting examples of the parallel I/O devices may include the ultraviolet laser unit 1, the plasma generators 4 and 4A, the illumination unit 23, and the thermographic camera 61. The serial I/O controller 1030 may be coupled to a plurality of serial I/O devices operable to perform communication with the processing unit 1000, and may control the communication performed between the processing unit 1000 and the serial I/O devices. Non-limiting examples of serial I/O devices may include the ultraviolet laser unit 1, the XYZ stage 7, and the stage 11A. The A/D and D/A converter 1040 may be coupled to analog devices such as various kinds of sensors through respective analog ports. Non-limiting examples of the sensors may include the two-dimensional image sensor 22. The A/D and D/A converter 1040 may control communication performed between the processing unit 1000 and the analog devices, and may perform analog-to-digital conversion and digital-to-analog conversion of contents of the communication.

The user interface 1010 may provide an operator with display showing a progress of the execution of the programs executed by the processing unit 1000, such that the operator is able to instruct the processing unit 1000 to stop execution of the programs or to execute an interruption routine.

The exemplary hardware environment 100 may be applied to one or more of configurations of the controller 9 and other controllers according to any example embodiment of the present disclosure. A person skilled in the art will appreciate that such controllers may be executed in a distributed computing environment, namely, in an environment where tasks may be performed by processing units linked through any communication network. In any example embodiment of the present disclosure, the controller 9 and other controllers may be coupled to one another through a communication network such as Ethernet (Registered Trademark) or the Internet. In the distributed computing environment, the program module may be stored in each of local and remote memory storage devices.

### 10. Et Cetera

The foregoing description is intended to be merely illustrative rather than limiting. It should therefore be appreciated that variations may be made in example embodiments of the present disclosure by persons skilled in the art without departing from the scope as defined by the appended claims.

The terms used throughout the specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items. Also, the singular forms “a”, “an”, and the used in the specification and the appended claims include plural references unless expressly and unequivocally limited to one referent.

What is claimed is:

1. A laser irradiation apparatus, comprising:
a plasma generator configured to supply an atmospheric pressure plasma to a predetermined region on a semiconductor material, the atmospheric pressure plasma containing a dopant;
a laser unit configured to output a pulsed laser light beam; and
a controller configured to control the plasma generator and the laser unit to perform one of a first control and a second control to thereby perform doping of the dopant into the semiconductor material, the first control causing irradiation of the predetermined region with one or more pulses of the pulsed laser light beam from start to finish of supply of the atmospheric pressure plasma to the predetermined region, and the second control causing irradiation of the predetermined region with one or more pulses of the pulsed laser light beam after supply of the atmospheric pressure plasma to the predetermined region.

2. The laser irradiation apparatus according to claim 1, wherein photon energy of the pulsed laser light beam is higher than a band gap of the semiconductor material.

3. The laser irradiation apparatus according to claim 2, wherein a wavelength of the pulsed laser light beam lies in a range from 157 nanometers to 380 nanometers both inclusive.

4. The laser irradiation apparatus according to claim 2, wherein a pulse width of the pulsed laser light beam lies in a range from one nanosecond to 1000 nanoseconds both inclusive.

5. The laser irradiation apparatus according to claim 2, wherein a pulse width of the pulsed laser light beam lies in a range from 10 nanoseconds to 100 nanoseconds both inclusive.

6. The laser irradiation apparatus according to claim 2, wherein the laser unit includes a laser medium containing one or more selected from the group consisting of F₂, ArF, KrF, XeCl, and XeF.

7. The laser irradiation apparatus according to claim 2, wherein the dopant includes one or more selected from the group consisting of nitrogen (N), phosphorus (P), boron (B), and arsenic (As).

8. A laser irradiation method, comprising:
supplying an atmospheric pressure plasma to a predetermined region on a semiconductor material, the atmospheric pressure plasma containing a dopant;
outputting a pulsed laser light beam; and
performing one of a first control and a second control to thereby perform doping of the dopant into the semiconductor material, the first control causing irradiation of the predetermined region with one or more pulses of the pulsed laser light beam from start to finish of supply of the atmospheric pressure plasma to the predetermined region, and the second control causing irradiation of the predetermined region with one or more pulses of the pulsed laser light beam after supply of the atmospheric pressure plasma to the predetermined region.
